(19) United States
(12) Patent Application Publication
(10) Pub. No.: US 2025/0023523 A1
(43) Pub. Date: Jan. 16, 2025

(54) PEAKING ADJUSTMENT CIRCUIT

(71) Applicant: SUMITOMO ELECTRIC INDUSTRIES, LTD., Osaka-shi (JP)

(72) Inventors: Hiroshi UEMURA, Osaka-shi (JP); Keiji Tanaka, Osaka-shi (JP)

(73) Assignee: SUMITOMO ELECTRIC INDUSTRIES, LTD., Osaka (JP)

(21) Appl. No.: 18/762,755

(22) Filed: Jul. 3, 2024

(30) Foreign Application Priority Data
Jul. 10, 2023 (JP) 2023-112919
Sep. 25, 2023 (JP) 2023-160163

(51) Int. Cl. H03F 1/42

(52) U.S. Cl. CPC H03F 1/42; H03F 2200/36

(57) ABSTRACT

A peaking adjustment circuit according to the present disclosure includes an amplifier circuit including a first node to which a first input signal is input and a second node as an output node, an adjustment circuit including a third node as an output node, a first inductor connected between the second node and the third node, and a first series circuit connected between the third node and a ground wiring and having a first capacitor and a first variable resistance element connected in series with each other, and a follower circuit including a fourth node as an output node, and a first source follower circuit connected between the third node and the fourth node, and the first variable resistance element has a first resistance value that changes according to a first setting signal.

### CROSS-REFERENCE TO RELATED APPLICATION

This application claims priorities from Japanese Patent Application No. 2023-112919, filed on Jul. 10, 2023 and Japanese Patent Application No. 2023-160163, filed on Sep. 25, 2023, the entire subject matters of which are incorporated herein by reference.

### TECHNICAL FIELD

The present disclosure relates to a peaking adjustment circuit.

### BACKGROUND ART

WO 2007/110915 describes a circuit that controls peaking of a circuit that transmits a high-frequency signal. This circuit includes a peaking detection unit that monitors a signal of an output unit and detects a peaking amount, and a control signal generation unit that varies a circuit parameter of the inductor peaking circuit on the basis of the peaking amount detected by the peaking detection unit.

### SUMMARY OF THE INVENTION

A peaking adjustment circuit according to an aspect of the present disclosure includes an amplifier circuit including a first node to which a first input signal is input and a second node as an output node, an adjustment circuit including a third node as an output node, a first inductor connected between the second node and the third node, and a first series circuit connected between the third node and a ground wiring and having a first capacitor and a first variable resistance element connected in series with each other, and a follower circuit including a fourth node as an output node, and a first source follower circuit connected between the third node and the fourth node, and the first variable resistance element has a first resistance value that changes according to a first setting signal.

### BRIEF DESCRIPTION OF THE DRAWINGS

FIG. 1 is a plan view illustrating a configuration of an optical transmission module according to an embodiment of the present disclosure;

FIG. 2 is a circuit diagram illustrating a detailed configuration of a driver IC in FIG. 1;

FIG. 3 is a circuit diagram illustrating a configuration example of variable resistance elements in FIG. 2;

FIG. 4 is a graph illustrating frequency characteristics of small signal responses at output nodes in the driver IC of the present embodiment;

FIG. 5 is a graph illustrating frequency characteristics of small signal responses at output nodes in the driver IC according to a comparative example;

FIG. 6 is a graph illustrating frequency characteristics of small signal responses at output nodes in the driver IC of the present embodiment;

FIG. 7 is a circuit diagram illustrating a configuration of a driver IC according to a modification of the present disclosure;

FIG. 8 is a circuit diagram illustrating a configuration of a driver IC according to a modification of the present disclosure; and

FIG. 9 is a circuit diagram illustrating a configuration of a driver IC according to a modification of the present disclosure.

### DETAILED DESCRIPTION

In the conventional circuit, the peak frequency is not stabilized in the adjustment of the peaking amount, and the frequency characteristics of output signals tends to greatly fluctuate by the adjustment.

An object of the present disclosure is to provide a peaking adjustment circuit capable of stabilizing frequency characteristics of output signals after adjustment.

In order to solve the above issue, the peaking adjustment circuit according to a first aspect of the present disclosure includes an amplifier circuit including a first node to which a first input signal is input and a second node as an output node, an adjustment circuit including a third node as an output node, a first inductor connected between the second node and the third node, and a first series circuit connected between the third node and a ground wiring and having a first capacitor and a first variable resistance element connected in series with each other, and a follower circuit including a fourth node as an output node, and a first source follower circuit connected between the third node and the fourth node, and the first variable resistance element has a first resistance value that changes according to a first setting signal.

According to the above-described first aspect, the first input signal input to the first node is amplified by the amplifier circuit, and is generated as the first output signal in the third node via the second node, the first inductor, and the first series circuit. Further, the first output signal is output from the fourth node via the first source follower circuit. In such a configuration, the first variable resistance element in the first series circuit is set to a variable first resistance value by the first setting signal. Therefore, the peak frequency of the first output signal can be stabilized while the peak amount of the first output signal is adjusted. As a result, the frequency characteristics of the output signals adjusted by the peaking adjustment circuit of the present embodiment can be stabilized.

According to the peaking adjustment circuit according to a second aspect of the present disclosure, in the above-described first aspect, the first series circuit is a circuit in which the first capacitor and the first variable resistance element are connected in the order of the first capacitor, the first variable resistance element, between the third node and the ground wiring. In this case, the fluctuation of the resistance value can be suppressed by stabilizing the voltage of the setting signal for setting the resistance value of the first variable resistance element with respect to the ground potential of the ground wiring. As a result, the frequency characteristics of the output signals can be easily stabilized.

In addition, according to the peaking adjustment circuit according to a third aspect of the present disclosure, in the above-described second aspect, the first variable resistance element includes a field effect transistor having a drain connected to the first capacitor, a source connected to the ground wiring, and a gate to which the first setting signal is input. In this case, when the source is grounded and the setting signal is input to the gate, the first variable resistance element in which the resistance value between the drain and the source can be variably set according to the voltage of the setting signal can be easily realized. As a result, the frequency characteristics of the output signals can be easily stabilized.

Further, according to the peaking adjustment circuit according to a fourth aspect of the present disclosure, in any one of the above-described first to third aspects, the follower circuit further includes a first emitter follower circuit connected in cascade to the first source follower circuit between the first source follower circuit and the fourth node. With such a configuration, the circuit connected to the output of the peaking adjustment circuit can be stably driven with respect to the change in the operating temperature, and the strength of the output signal can be stabilized.

Further, a peaking adjustment circuit according to a fifth aspect of the present disclosure includes an amplifier circuit including a first node to which a first input signal is input, a fifth node to which a second input signal is input, and a second node and a sixth node as output nodes, an adjustment circuit including a third node and a seventh node as output nodes, a first inductor connected between the second node and the third node, a first series circuit connected between the third node and a ground wiring and having a first capacitor and a first variable resistance element connected in series with each other, a second inductor connected between the sixth node and the seventh node, and a second series circuit connected between the seventh node and the ground wiring and having a second capacitor and a second variable resistance element connected in series with each other, and a follower circuit including a fourth node and an eighth node as output nodes, a first source follower circuit connected between the third node and the fourth node, and a second source follower circuit connected between the seventh node and the eighth node, and the first variable resistance element has a first resistance value that changes according to a first setting signal, and the second variable resistance element has a second resistance value that changes according to a second setting signal.

According to the above-described fifth aspect, the first input signal input to the first node and the second input signal input to the fifth node are amplified by the amplifier circuit, generated as the first output signal in the third node via the second node, the first inductor, and the first series circuit, and generated as the second output signal in the seventh node via the sixth node, the second inductor, and the second series circuit. Further, the first output signal is output from the fourth node via the first source follower circuit, and the second output signal is output from the eighth node via the second source follower circuit. In such a configuration, the first variable resistance element in the first series circuit is set to a variable first resistance value by the first setting signal, and the second variable resistance element in the second series circuit is set to a variable second resistance value by the second setting signal. Therefore, the peak frequency of the first output signal and the second output signal can be stabilized while the peak amounts of these signals are adjusted. As a result, the frequency characteristics of the output signals adjusted by the peaking adjustment circuit of the present embodiment can be stabilized.

Further, according to a peaking adjustment circuit according to a sixth aspect of the present disclosure, in the above-described fifth aspect, the first series circuit is a circuit in which the first capacitor and the first variable resistance element are connected in the order of the first capacitor, the first variable resistance element, between the third node and the ground wiring, and the second series circuit is a circuit in which the second capacitor and the second variable resistance element are connected in the order of the second capacitor, the second variable resistance element, between the seventh node and the ground wiring. According to such a configuration, the fluctuation of the first resistance value can be suppressed by stabilizing the voltage of the setting signal (the first setting signal) for setting the resistance value (the first resistance value) of the first variable resistance element with respect to the ground potential of the ground wiring. In addition, the fluctuation of the second resistance value can be suppressed by stabilizing the voltage of the setting signal (the second setting signal) for setting the resistance value (the second resistance value) of the second variable resistance element with respect to the ground potential of the ground wiring. As a result, the frequency characteristics of the output signals can be easily stabilized.

In addition, according to a peaking adjustment circuit according to a seventh aspect of the present disclosure, in the above-described sixth aspect, the first variable resistance element includes a field effect transistor having a drain connected to the first capacitor, a source connected to the ground wiring, and a gate to which the first setting signal is input, and the second variable resistance element includes a field effect transistor having a drain connected to the second capacitor, a source connected to the ground wiring, and a gate to which the second setting signal is input. In the case of such a configuration, when the source is grounded and the first setting signal is input to the gate, the first variable resistance element in which the resistance value (the first resistance value) between the drain and the source can be variably set according to the voltage of the first setting signal can be easily realized. Further, when the source is grounded and the second setting signal is input to the gate, the second variable resistance element in which the resistance value (the second resistance value) between the drain and the source can be variably set according to the voltage of the second setting signal can be easily realized. As a result, the frequency characteristics of the output signals can be easily stabilized.

In addition, according to a peaking adjustment circuit according to an eighth aspect of the present disclosure, in any one of the above-described fifth to seventh aspects, the follower circuit further includes a first emitter follower circuit connected in cascade to the first source follower circuit between the first source follower circuit and the fourth node, and a second emitter follower circuit connected in cascade to the second source follower circuit between the second source follower circuit and the eighth node. According to such a configuration, the circuit connected to the output of the peaking adjustment circuit can be stably driven with respect to the change in the operating temperature, and the strength of the output signal can be stabilized.

In addition, according to a peaking adjustment circuit according to a ninth aspect of the present disclosure, in any one of the above-described fifth to eighth aspects, an inductance of the first inductor is equal to an inductance of the second inductor, a capacitance value of the first capacitor is equal to a capacitance value of the second capacitor, and a resistance value of the first variable resistance element and a resistance value of the second variable resistance element are set equal to each other. According to such a configuration, the peak amounts and the peak frequencies in the first output signal and the second output signal can be matched, and the characteristics of the pair of output signals (that is, one differential signal) adjusted by the peaking adjustment circuit can be stabilized.

A peaking adjustment circuit according to a tenth aspect of the present disclosure includes an amplifier circuit including a first node to which a first input signal is input and a second node as an output node, and generating an amplified signal having peaking characteristics according to the first input signal in the output node, an adjustment circuit including a third node, and a first series circuit connected between the third node and a ground wiring and having a first capacitor and a first variable resistance element connected in series with each other, and a follower circuit including a fourth node as an output node, and a first source follower circuit connected between the third node and the fourth node, and the first variable resistance element has a first resistance value that changes according to a first setting signal.

According to the above-described tenth aspect, the first input signal input to the first node is amplified by the amplifier circuit so as to have a peaking characteristic, and is generated as the first output signal in the third node via the second node and the first series circuit. Further, the first output signal is output from the fourth node via the first source follower circuit. In such a configuration, the first variable resistance element in the first series circuit is set to a variable first resistance value by the first setting signal. Therefore, the peak frequency of the first output signal can be stabilized while the peak amount of the first output signal is adjusted. As a result, the frequency characteristics of the output signals adjusted by the peaking adjustment circuit of the present embodiment can be stabilized.

A peaking adjustment circuit according to an eleventh aspect of the present disclosure includes an amplifier circuit including a first node to which a first input signal is input, a fifth node to which a second input signal is input, and a second node and a sixth node as output nodes, and generating an amplified signal having peaking characteristics according to the first input signal and the second input signal in the output node, an adjustment circuit including a third node and a seventh node as output nodes, a first series circuit connected between the third node and a ground wiring and having a first capacitor and a first variable resistance element connected in series with each other, and a second series circuit connected between the seventh node and the ground wiring and having a second capacitor and a second variable resistance element connected in series with each other, and a follower circuit including a fourth node and an eighth node as output nodes, a first source follower circuit connected between the third node and the fourth node, and a second source follower circuit connected between the seventh node and the eighth node, and the first variable resistance element has a first resistance value that changes according to a first setting signal, and the second variable resistance element has a second resistance value that changes according to a second setting signal.

According to the above-described eleventh aspect, the first input signal input to the first node and the second input signal input to the fifth node are amplified by the amplifier circuit so as to have a peaking characteristic, generated as the first output signal in the third node via the second node and the first series circuit, and generated as the second output signal in the seventh node via the sixth node and the second series circuit. Further, the first output signal is output from the fourth node via the first source follower circuit, and the second output signal is output from the eighth node via the second source follower circuit. In such a configuration, the first variable resistance element in the first series circuit is set to a variable first resistance value by the first setting signal, and the second variable resistance element in the second series circuit is set to a variable second resistance value by the second setting signal. Therefore, the peak frequency of the first output signal and the second output signal can be stabilized while the peak amounts of these signals are adjusted. As a result, the frequency characteristics of the output signals adjusted by the peaking adjustment circuit of the present embodiment can be stabilized.

Hereinafter, embodiments of the present disclosure will be described with reference to the drawings. In the description of the drawings, the same elements are denoted by the same reference signs, and a repeated description is omitted.

### (Configuration of Optical Transmission Module)

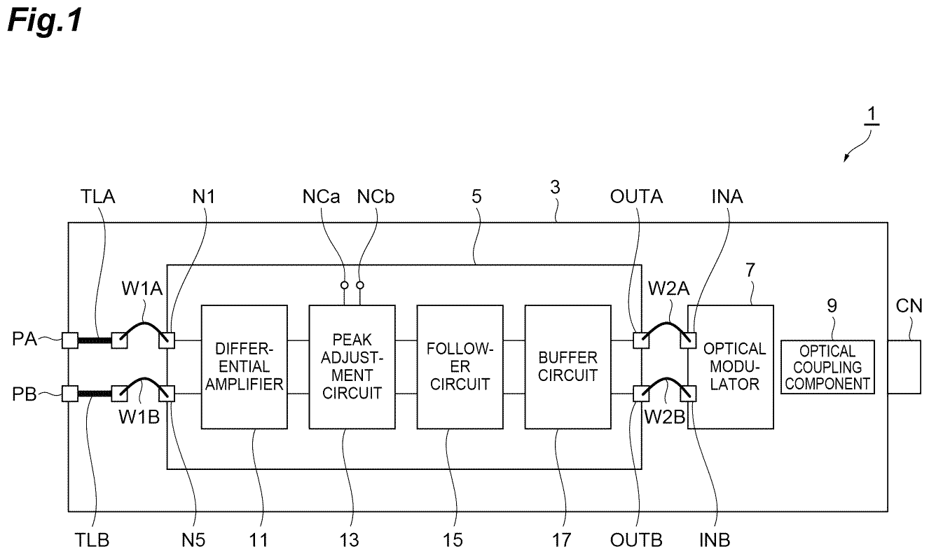

FIG. 1 is a block diagram illustrating a schematic configuration of an optical transmission module 1 according to an embodiment of the present disclosure. The optical transmission module 1 is a module that converts an electrical signal into an optical signal for optical signal transmission.

As illustrated in FIG. 1, the optical transmission module 1 includes a package 3, two signal pads PA and PB and an optical connector CN provided in the package 3, and a driver integrated circuit (IC) 5, an optical modulator 7, and an optical coupling component 9 mounted in the package 3. A positive-phase signal (first input signal) and a negative-phase signal (second input signal), which are analog signals, are applied externally to the two signal pads PA and PB, respectively. The positive-phase signal and the negative-phase signal are signals having equal amplitudes and phases opposite to each other, that is, so-called differential signals.

The signal pad PA is electrically connected to a node (first node) N1 which is a terminal of a driver IC 5 via a transmission line TLA and a wire W1A inside the package 3, and the signal pad PB is electrically connected to a node (fifth node) N5 which is a terminal of the driver IC 5 via a transmission line TLB and a wire W1B inside the package 3. The positive-phase signal applied to the signal pad PA is input to the node N1, and the negative-phase signal applied to the signal pad PB is input to the node N5.

The optical modulator 7 is a circuit that generates an optical signal based on two current signals that are differential signals output from the driver IC 5. As the optical modulator 7, for example, a Mach-Zehnder modulator is used. The optical modulator 7 has two nodes INA and INB as input terminals, the node INA is electrically connected to an output node OUTA which is an output terminal of the driver IC 5 via a wire W2A, and the node INB is electrically connected to an output node OUTB which is an output terminal of the driver IC 5 via a wire W2B. A current signal that is a positive-phase signal output from the output node OUTA is input to the node INA, and a current signal that is a negative-phase signal output from the output node OUTB is input to the node INB. The optical signal generated by the optical modulator 7 is output externally via the optical coupling component 9 and the optical connector CN.

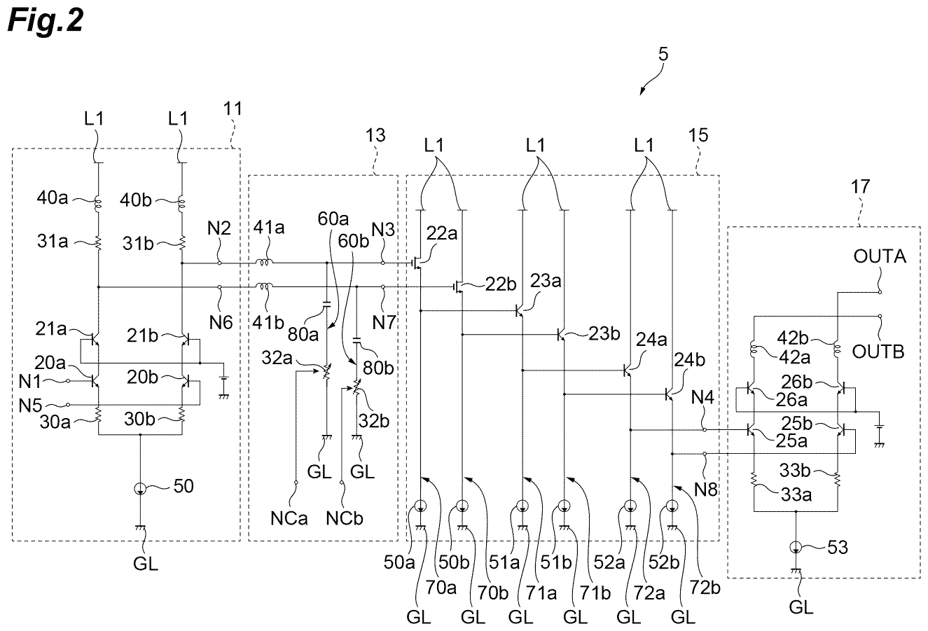

FIG. 2 is a circuit diagram illustrating a detailed configuration of the driver IC 5.

As illustrated in FIG. 2, the driver IC 5 includes a differential amplifier (amplifier circuit) 11, a peak adjustment circuit (also simply referred to as an adjustment circuit) 13, a follower circuit 15, and a buffer circuit 17. The differential amplifier 11, the peak adjustment circuit 13, and the follower circuit 15 constitute a peaking adjustment circuit of the present embodiment.

The differential amplifier 11 is an integrated circuit that modulates an output current based on a pair of differential signals input from the two nodes N1 and N5. The differential amplifier 11 includes bipolar transistors 20a, 20b, 21a, and 21b, resistance elements 30a, 30b, 31a, and 31b, inductors 40a and 40b, a current source 50, an output node (second node) N2, and an output node (sixth node) N6.

In the bipolar transistors 20a and 20b, respective bases are connected to the nodes N1 and N5, respective collectors are connected to the emitters of the bipolar transistors 21a and 21b, and the respective emitters are connected to one end of the current source 50 via the resistance elements 30a and 30b. These bipolar transistors 20a and 20b modulate the collector current with the input differential signal. In the bipolar transistors 21a and 21b, respective bases are set to a predetermined DC voltage, respective emitters are connected to collectors of the bipolar transistors 20a and 20b, and respective collectors are connected to a power supply line L1 to which a predetermined power supply potential (for example, 3.3 V) is applied via the resistance elements 31a and 31b and the inductors 40a and 40b. These bipolar transistors 21a and 21b are cascode transistors having a base to which a DC voltage is applied. The resistance elements 30a and 30b are degeneration resistors that enable expansion of the linear input range of the driver IC 5. The current source 50 has one end connected to the emitters of the bipolar transistors 20a and 20b via the resistance elements 30a and 30b, has the other end connected to a ground line (ground wiring) GL set to a ground potential, and supplies the emitter current of the bipolar transistors 20a and 20b. The resistance elements 31a and 31b are loads for converting collector currents modulated by the bipolar transistors 20a and 20b into voltage signals.

According to the differential amplifier 11 having such a configuration, each of the collector currents of the bipolar transistors 20a and 20b is modulated by the differential signals input from the nodes N1 and N5, whereby two output signals which are differential signals are generated at the output nodes N2 and N6 connected to the collectors of the bipolar transistors 21a and 21b.

The peak adjustment circuit 13 is a circuit that adjusts frequency characteristics of two output signals generated at the output nodes N2 and N6. The peak adjustment circuit 13 includes an output node (third node) N3, an output node (seventh node) N7, control nodes NCa and NCb, an inductor (first inductor) 41a, an inductor (second inductor) 41b, a series circuit (first series circuit) 60a including a capacitor (first capacitor) 80a and a variable resistance element (first variable resistance element) 32a, and a series circuit (second series circuit) 60b including a capacitor (second capacitor) 80b and a variable resistance element (second variable resistance element) 32b.

The inductor 41a is connected between the output node N2 and the output node N3. The inductor 41a has a function of causing peaking characteristics to be described later in a signal generated at the output node N3. That is, the maximum peaking amount in the peaking adjustment can be set by changing the inductance of the inductor 41a. The series circuit 60a is a circuit configured by connecting the capacitor 80a and the variable resistance element 32a in series in this order between the output node N3 and the ground line GL. The variable resistance element 32a is an element whose resistance value (first resistance value) can be variably adjusted according to the first setting signal input externally via the control node NCa.

The inductor 41b is connected between the output node N6 and the output node N7. The inductor 41b has a function of causing peaking characteristics to be described later in a signal generated at the output node N7. That is, the maximum peaking amount in the peaking adjustment can be set by changing the inductance of the inductor 41b. The series circuit 60b is a circuit configured by connecting the capacitor 80b and the variable resistance element 32b in series in this order between the output node N7 and the ground line GL. The variable resistance element 32b is an element whose resistance value (second resistance value) can be variably adjusted according to the second setting signal input externally via the control node NCb.

In the peak adjustment circuit 13 having the above configuration, the inductance of the inductor 41a and the inductance of the inductor 41b are set to be equal, the capacitance (capacitance value) of the capacitor 80a and the capacitance of the capacitor 80b are set to be equal, and the resistance value of the variable resistance element 32a and the resistance value of the variable resistance element 32b are set to be always equal.

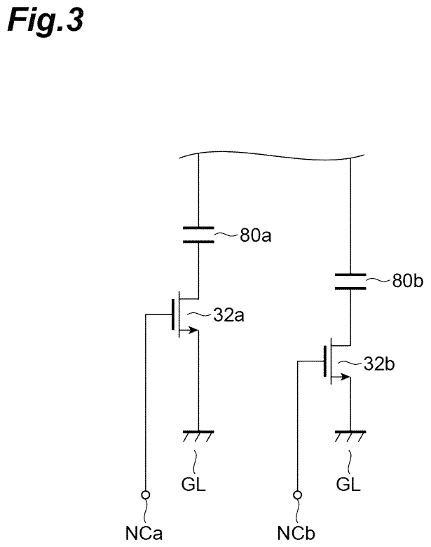

FIG. 3 is a circuit diagram illustrating a configuration example of variable resistance elements 32a and 32b. The variable resistance elements 32a and 32b include, for example, a field effect transistor (FET). In the variable resistance element 32a that is an FET, a drain is connected to the capacitor 80a, a source is connected to the ground line GL, a gate is connected to the control node NCa, and a first setting signal that is a voltage signal is applied to the gate. In the variable resistance element 32b that is an FET, a drain is connected to the capacitor 80b, a source is connected to the ground line GL, a gate is connected to the control node NCb, and a second setting signal that is a voltage signal is applied to the gate. As described above, in order to set the resistance value of the variable resistance element 32a and the resistance value of the variable resistance element 32b to be equal, the size of the FET constituting the variable resistance element 32a is set to be equal to the size of the FET constituting the variable resistance element 32b, and the voltage value of the first setting signal and the voltage value of the second setting signal are set to be equal to each other.

Returning to FIG. 2, the follower circuit 15 is a circuit that generates two output signals following two output signals generated at the output nodes N3 and N7. The follower circuit 15 includes an output node (fourth node) N4, an output node (eighth node) N8, and a source follower circuit (first source follower circuit) 70a, an emitter follower circuit (first emitter follower circuit) 71a, and an emitter follower circuit 72a that are connected in cascade in this order between the output node N3 and the output node N4, and a source follower circuit (second source follower circuit) 70b, an emitter follower circuit (second emitter follower circuit) 71b, and an emitter follower circuit 72b that are connected in cascade in this order between the output node N7 and the output node N8.

The source follower circuit 70a includes an FET 22a and a current source 50a. In the FET 22a, a gate is connected to the output node N3, a drain is connected to the power supply line L1, and a source is connected to the ground line GL via the current source 50a. The source follower circuit 70b includes an FET 22b and a current source 50b. In the FET 22b, a gate is connected to the output node N7, a drain is connected to the power supply line L1, and a source is connected to the ground line GL via the current source 50b. These FETs 22a and 22b generate signals following the two output signals output from the output nodes N3 and N7, respectively, and output the signals from the respective sources. The current sources 50a and 50b supply the source currents of the FETs 22a and 22b, respectively.

The emitter follower circuit 71a includes a bipolar transistor 23a and a current source 51a. In the bipolar transistor 23a, a base is connected to the source of the FET 22a, a collector is connected to the power supply line L1, and an emitter is connected to the ground line GL via the current source 51a. The emitter follower circuit 71b includes a bipolar transistor 23b and a current source 51b. In the bipolar transistor 23b, a base is connected to the source of the FET 22b, a collector is connected to the power supply line L1, and an emitter is connected to the ground line GL via the current source 51b. These bipolar transistors 23a and 23b generate signals following two output signals output from the FETs 22a and 22b, respectively, and output the signals from the respective emitters. The current sources 51a and 51b supply emitter currents of the bipolar transistors 23a and 23b, respectively.

The emitter follower circuit 72a includes a bipolar transistor 24a and a current source 52a. In the bipolar transistor 24a, a base is connected to the emitter of the bipolar transistor 23a, a collector is connected to the power supply line L1, and an emitter is connected to the ground line GL via the current source 52a and also connected to the output node N4. The emitter follower circuit 72b includes a bipolar transistor 24b and a current source 52b. In the bipolar transistor 24b, a base is connected to the emitter of the bipolar transistor 23b, a collector is connected to the power supply line L1, and an emitter is connected to the ground line GL via the current source 52b and also connected to the output node N8. These bipolar transistors 24a and 24b generate signals following two output signals output from the bipolar transistors 23a and 23b, respectively, and output the signals from the respective emitters. The current sources 52a and 52b supply emitter currents of the bipolar transistors 24a and 24b, respectively.

The buffer circuit 17 is a circuit that generates two current signals, which are differential signals for driving the optical modulator 7, based on the two output signals output from the output nodes N4 and N8. The buffer circuit 17 includes output nodes OUTA and OUTB, bipolar transistors 25a, 25b, 26a, and 26b, resistance elements 33a and 33b, inductors 42a and 42b, and a current source 53.

In the bipolar transistors 25a and 25b, respective bases are connected to the output nodes N4 and N8, respective collectors are connected to the emitters of the bipolar transistors 26a and 26b, and the respective emitters are connected to one end of the resistance elements 33a and 33b. The bipolar transistors 25a and 25b modulate the collector current with respective output signals output from the output nodes N4 and N8.

In the bipolar transistors 26a and 26b, respective bases are set to predetermined DC voltages, respective emitters are connected to the collectors of the bipolar transistors 25a and 25b, and respective collectors are connected to the output nodes OUTB and OUTA via the inductors 42a and 42b. These bipolar transistors 26a and 26b are cascode transistors. The presence of the cascode transistor makes it possible to widen the bandwidth of the output current and improve the voltage gain of the buffer circuit 17.

One end of each of the resistance elements 33a and 33b is connected to the emitter of each of the bipolar transistors 25a and 25b, and the other end is connected to the ground line GL via the current source 53. These resistance elements 33a and 33b are degeneration resistors, and enable expansion of a linear input range of the buffer circuit 17.

By the driver IC 5 described above, the positive-phase signal input to the node N1 and the negative-phase signal input to the node N5 are amplified by the differential amplifier 11, generated as the output signal in the output node N3 via the output node N2, the inductor 41a, and the series circuit 60a, and generated as the output signal in the output node N7 via the output node N6, the inductor 41b, and the series circuit 60b. Further, the output signal output to the output node N3 is output from the output node N4 via the source follower circuit 70a, and the output signal output from the output node N7 is output from the output node N8 via the source follower circuit 70b. In such a configuration, the variable resistance element 32a in the series circuit 60a is set to a variable first resistance value by the first setting signal, and the variable resistance element 32b in the series circuit 60b is set to a variable second resistance value by the second setting signal. Therefore, the peak frequency of the two output signals can be stabilized while the peak amounts of the two output signals are adjusted. As a result, the frequency characteristics of the output signals adjusted by the driver IC 5 of the present embodiment can be stabilized.

In the present embodiment, the series circuits 60a and 60b are configured as circuits in which the capacitors 80a and 80b and the variable resistance elements 32a and 32b are connected in this order between the output nodes N3 and N7 and the ground line GL. The fluctuation of the first resistance value can be suppressed by stabilizing the voltage of the setting signal (the first setting signal) for setting the resistance value (the first resistance value) of the variable resistance element 32a with respect to the ground potential of the ground wiring. In addition, the fluctuation of the second resistance value can be suppressed by stabilizing the voltage of the setting signal (the second setting signal) for setting the resistance value (the second resistance value) of the variable resistance element 32b with respect to the ground potential of the ground wiring. As a result, the frequency characteristics of the output signals of the driver IC 5 can be easily stabilized.

Further, in the present embodiment, the variable resistance elements 32a and 32b are configured by FETs. In the FET configuring the variable resistance element 32a, when the source is grounded and the first setting signal is input to the gate, the first variable resistance element in which the resistance value (the first resistance value) between the drain and the source can be variably set according to the voltage of the first setting signal can be easily realized. Furthermore, in the FET configuring the variable resistance element 32b, when the source is grounded and the second setting signal is input to the gate, the second variable resistance element in which the resistance value (the second resistance value) between the drain and the source can be variably set according to the voltage of the second setting signal can be easily realized. As a result, the frequency characteristics of the output signals of the driver IC 5 can be easily stabilized.

Furthermore, in the present embodiment, the follower circuit 15 further includes emitter follower circuits 71a, 71b, 72a, and 72b connected in cascade to the source follower circuits 70a and 70b, respectively, between the source follower circuits 70a and 70b and the output nodes N4 and N8. According to such a configuration, the load of the peak adjustment circuit 13 becomes the source follower circuit. The inventor of the present application has found that, in a case where the source follower circuits 70a and 70b are connected to the peak adjustment circuit 13 as in the present embodiment, the temperature dependence of the input impedance viewed from the peak adjustment circuit 13 is smaller than that in a case where the emitter follower circuit is connected to the peak adjustment circuit 13, and the temperature dependence of the peak adjustment circuit can be suppressed as described later. In addition, by cascade-connecting the emitter follower circuits 71a and 71b to the source follower circuits 70a and 70b, the buffer circuit 17, which is a large load, can be driven at a high speed. The emitter follower circuits 72a and 72b are further connected in cascade to the emitter follower circuits 71a and 71b, whereby a load driving capability can be enhanced. As a result, the output signal intensity of the driver IC 5 can be stabilized, and high-speed operation can be realized.

In addition, in the present embodiment, the inductance of the inductor 41a and the inductance of the inductor 41b are equal, the capacitance of the capacitor 80a and the capacitance of the capacitor 80b are equal, and the resistance value of the variable resistance element 32a and the resistance value of the variable resistance element 32b are set to be equal. In this case, the peak amount and the peak frequency of one signal of the pair of output signals (differential signals) of the peak adjustment circuit 13 can be matched with the peak amount and the peak frequency of the other signal, respectively, thereby suppressing generation of in-phase components and enabling stable operation of the driver IC 5 and the optical transmission module 1.

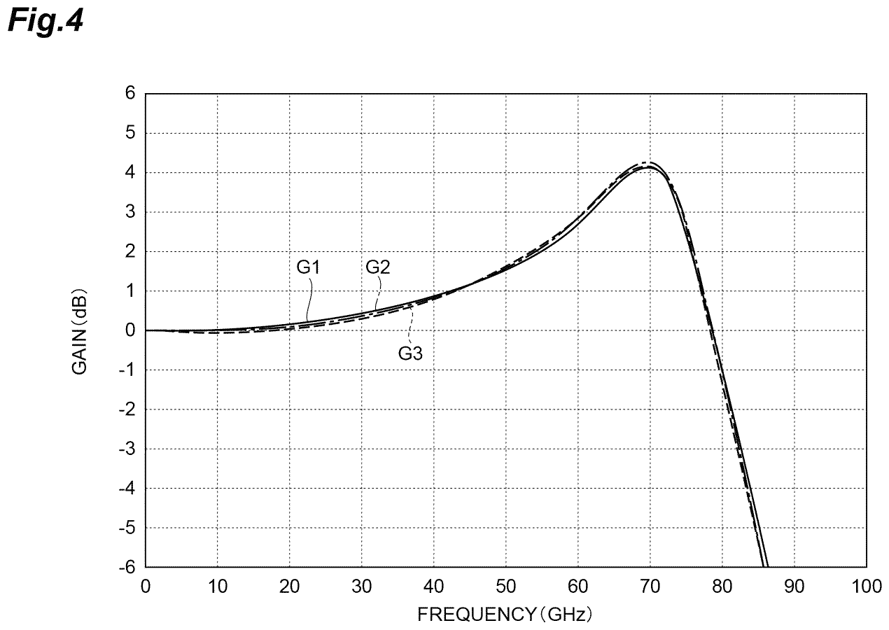

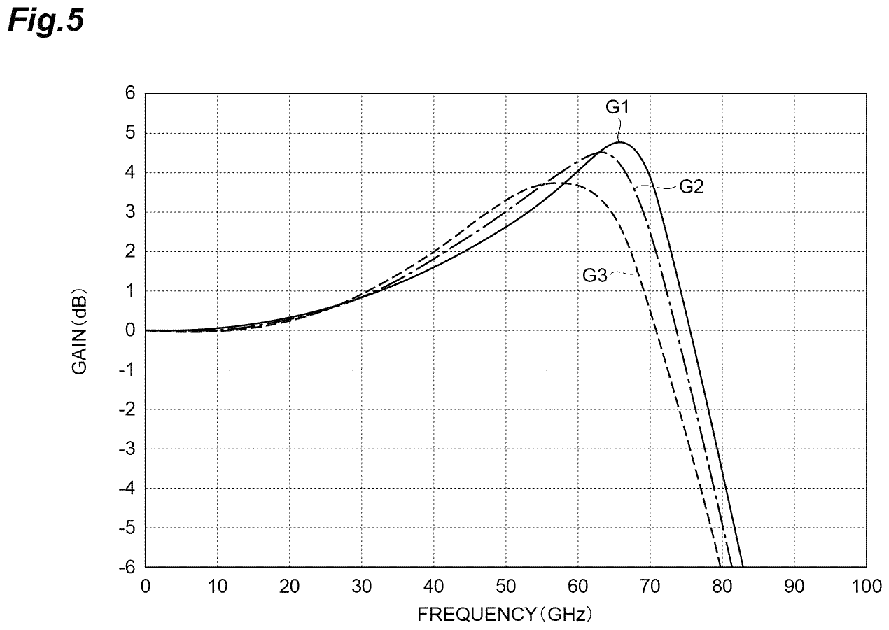

FIG. 4 is a graph illustrating frequency characteristics of small signal responses at the output nodes N3 and N7 in the driver IC 5 of the present embodiment, and FIG. 5 is a graph illustrating frequency characteristics of small signal responses at the output nodes N3 and N7 in a comparative example in which the source follower circuits 70a and 70b are removed from the driver IC 5. A pair of complementary signals (differential signals) is generated at the output nodes N3 and N7, and each graph indicates a frequency characteristic of the differential signal. In FIG. 4, each frequency characteristic indicates a characteristic in which the gain becomes the maximum value (peak value) at a frequency of 70 GHz and the gain decreases as the frequency increases when the frequency exceeds 70 GHz. Such frequency characteristics are also referred to as peaking characteristics. In each graph, a frequency characteristic normalized by a gain at 1 GHz at an environmental temperature of −5° C. is indicated by G1, a frequency characteristic normalized by a gain at 1 GHz at an environmental temperature of 45° C. is indicated by G2, and a frequency characteristic normalized by a gain at 1 GHz at an environmental temperature of 95° C. is indicated by G3. In the frequency characteristics as illustrated in each graph, the peak value is referred to as a peaking amount, and the frequency at which the gain becomes the peak value is referred to as a peak frequency. For example, changing the peaking amount of the output signal is referred to as peak adjustment or peaking adjustment. From the comparison between FIG. 4 and FIG. 5, it has been found that in the present embodiment, the temperature dependence of the small signal response is suppressed to be low due to the presence of the source follower circuits 70a and 70b. For example, in order to perform stable signal transmission, it is preferable that the temperature dependence of the small signal response is small.

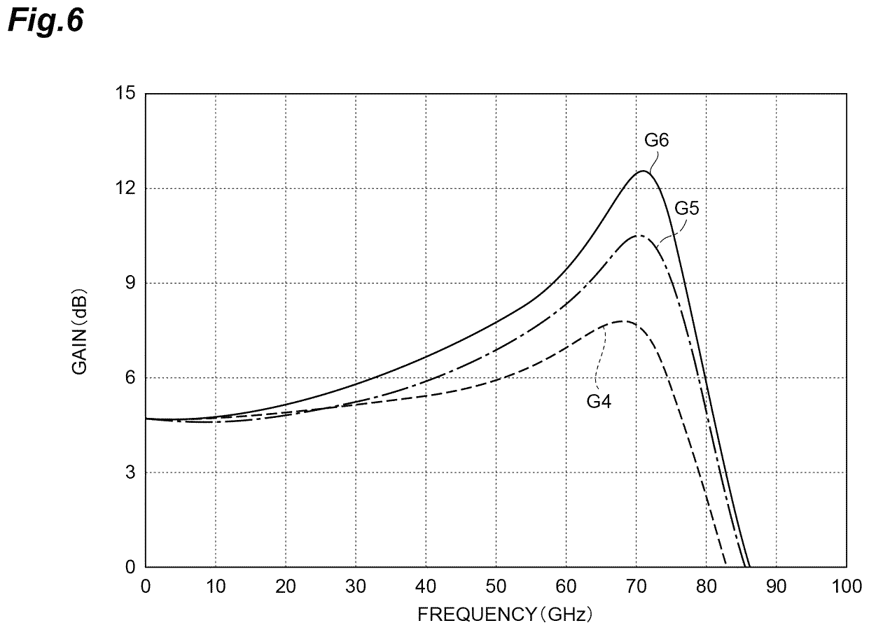

In addition, FIG. 6 is a graph illustrating frequency characteristics of small signal responses at output nodes N3 and N7 in the driver IC 5 of the present embodiment. In this graph, frequency characteristics in a case where the resistance values of the variable resistance elements 32a and 32b are set to be increased in three stages in order to adjust the peaking amount are indicated by G4, G5, and G6. At a low frequency (60 GHz or less) lower than the peak frequency (about 70 GHz), since the impedances of the capacitors 80a and 80b are large, the change in gain with respect to the change in the resistance value of the variable resistance elements 32a and 32b connected in series is relatively small. At a high frequency (80 GHz or more) higher than the peak frequency, the input impedances of the source follower circuits 70a and 70b when viewed from the peak adjustment circuit 13 are small, so that a change in gain with respect to a change in the resistance values of the variable resistance elements 32a and 32b is relatively small. On the other hand, in the frequency characteristics G4, G5, and G6 at the peak frequency, the change in gain with respect to the change in the resistance value of the variable resistance elements 32a and 32b is relatively large as compared with the low frequency and the high frequency. In particular, as is clear from the frequency characteristics G4, G5, and G6, according to the present embodiment, it has been found that the peak frequencies can be matched while changing the peak amount (peaking amount). Here, “matching of peak frequencies” means matching to an extent that a frequency error in a range of frequency ±5 GHz is allowed.

A preferable setting range of the circuit parameter in the peak adjustment circuit 13 of the present embodiment is as described below. Regarding the capacitors 80a and 80b, the upper limit value of the capacitance is set to such a value that the dependence of the impedance of the series circuits 60a and 60b on the variable resistance elements 32a and 32b becomes small at a low frequency. The lower limit value of the capacitance is set to such a value that the impedance of the series circuits 60a and 60b changes according to the variable resistance elements 32a and 32b near the peak frequency. Specifically, the capacitances of the capacitors 80a and 80b are set to, for example, 10 fF or more and 100 fF or less. Regarding the variable resistance elements 32a and 32b, the lower limit value of the resistance value is set to such a value that the band of the output signal does not deteriorate due to an increase in the load capacitance. Specifically, the resistance values of the variable resistance elements 32a and 32b are set to, for example, 50Ω or more.

In addition, according to the simulation result regarding the input capacitance of the follower circuit 15, according to the driver IC 5 of the present embodiment, it has been found that the input capacitance is in the range of 6.3 fF or more and 6.8 fF or less at the frequency of 70 GHz at the environmental temperature from −5° C. to 95° C. On the other hand, in the modification in which the source follower circuits 70a and 70b are removed in the configuration of the driver IC 5, it has been found that the input capacitance is in the range of 9.0 fF or more and 11.5 fF or less at the frequency of 70 GHz at the environmental temperature from −5° C. to 95° C. According to the simulation results, in the driver IC 5, by inserting the source follower circuits 70a and 70b having low temperature dependency of the input capacitance into the subsequent stage of the peak adjustment circuit 13 and the preceding stage of the emitter follower circuits 71a and 71b, it has been found that the influence of the temperature dependence of the input capacitances of the emitter follower circuits 71a and 71b can be reduced, and the fluctuation of the peak frequency of the output signal output from the driver IC 5 can be effectively suppressed.

Although the principles of the present disclosure have been illustrated and described above in the preferred embodiments, it is recognized by those skilled in the art that the present invention may be modified in arrangement and details without departing from such principles. For example, the source follower circuits 70a and 70b, the emitter follower circuits 71a and 71b, and the emitter follower circuits 72a and 72b may further include elements (resistance elements or transistors) for adjusting a DC potential. The present invention is not limited to the specific configuration disclosed in the present embodiment. Accordingly, all modifications and changes coming from the scope of the claims and the spirit thereof are claimed.

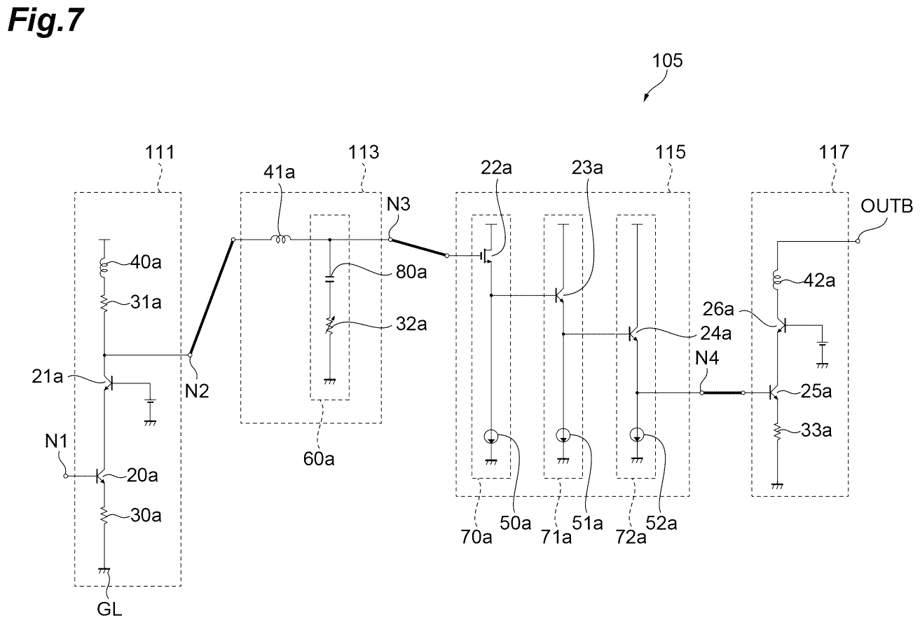

FIG. 7 is a circuit diagram illustrating a configuration of a driver IC 105 according to a modification of the present disclosure. The driver IC 105 is an embodiment in which the driver IC 5 is changed to a single-phase circuit.

That is, the driver IC 105 includes a node N1 and an amplifier (amplifier circuit) 111 including bipolar transistors 20a and 21a, resistance elements 30a and 31a, an inductor 40a, and an output node N2.

In addition, the driver IC 105 includes, as the peak adjustment circuit 113, an output node N3, an inductor 41a, and a series circuit 60a configured by a capacitor 80a and a variable resistance element 32a.

In addition, the driver IC 105 includes, as a follower circuit 115, an output node N4, a source follower circuit 70a, an emitter follower circuit 71a, and an emitter follower circuit 72a that are connected in cascade in this order between the output node N3 and the output node N4.

Further, the driver IC 105 includes, as a buffer circuit 117, an output node OUTB, bipolar transistors 25a and 26a, a resistance element 33a, and an inductor 42a. The single-phase signal input to the node N1 is output as a single-phase signal from the output node OUTB.

According to such a modification, even in a configuration in which a circuit in the subsequent stage is driven by a single-phase signal, the frequency characteristics of the output signal adjusted by the driver IC 105 can be stabilized.

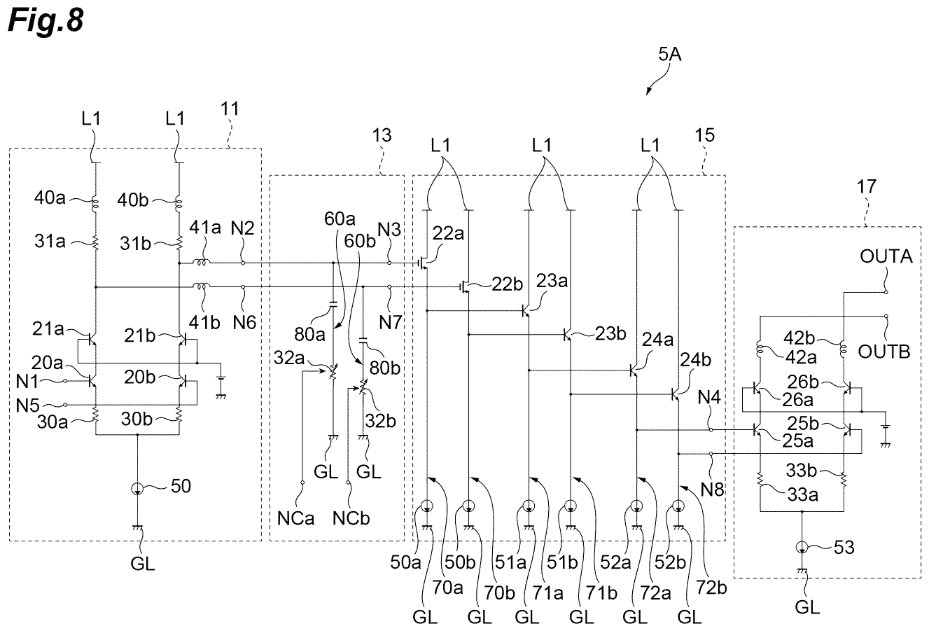

FIG. 8 is a circuit diagram illustrating a configuration of a driver IC 5A according to a modification of the present disclosure. The driver IC 5A is an embodiment in which the driver IC 5 is changed so that the differential amplifier 11 has a function of causing peaking characteristics.

In other words, the driver IC 5A includes a differential amplifier (amplifier circuit) 11, a peak adjustment circuit 13, a follower circuit 15, and a buffer circuit 17. The differential amplifier 11, the peak adjustment circuit 13, and the follower circuit 15 constitute a peaking adjustment circuit of the present modification.

The differential amplifier 11 is an integrated circuit that modulates an output current based on a pair of differential signals input from the two nodes N1 and N5. The differential amplifier 11 includes bipolar transistors 20a, 20b, 21a, and 21b, resistance elements 30a, 30b, 31a, and 31b, inductors 40a and 40b, a current source 50, inductors 41a and 41b, an output node (second node) N2, and an output node (sixth node) N6.

In the bipolar transistors 20a and 20b, respective bases are connected to the nodes N1 and N5, respective collectors are connected to the emitters of the bipolar transistors 21a and 21b, and the respective emitters are connected to one end of the current source 50 via the resistance elements 30a and 30b. These bipolar transistors 20a and 20b modulate the collector current with the input differential signal. In the bipolar transistors 21a and 21b, respective bases are set to a predetermined DC voltage, respective emitters are connected to collectors of the bipolar transistors 20a and 20b, and respective collectors are connected to a power supply line L1 to which a predetermined power supply potential (for example, 3.3 V) is applied via the resistance elements 31a and 31b and the inductors 40a and 40b. These bipolar transistors 21a and 21b are cascode transistors having a base to which a DC voltage is applied.

The inductors 40a and 40b are inductors for shunt peaking, and are also called shunt inductors. The inductors 40a and 40b enable widening of the bandwidth of the differential amplifier 11. The inductors 41a and 41b are connected between the collectors of the bipolar transistors 21b and 21a and the output nodes N2 and N6, respectively. The inductors 41a and 41b are inductors for series peaking, and are also called series inductors. The inductors 41a and 41b enable widening of the bandwidth of the differential amplifier 11, similar to the shunt inductor. The differential amplifier 11 includes at least one of the inductors 40a and 40b and the inductors 41a and 41b, and the other may be omitted. As a result, the frequency response of the differential amplifier 11 has a peak shape having a higher gain in a specific frequency range than in other frequency ranges. That is, the differential amplifier 11 generates a differential signal having peaking characteristics according to the differential signals input at the output nodes N2 and N6.

The resistance elements 30a and 30b are degeneration resistors that enable expansion of the linear input range of the driver IC 5A. The current source 50 has one end connected to the emitters of the bipolar transistors 20a and 20b via the resistance elements 30a and 30b, has the other end connected to a ground line (ground wiring) GL set to a ground potential, and supplies the emitter current of the bipolar transistors 20a and 20b. The resistance elements 31a and 31b are loads for converting collector currents modulated by the bipolar transistors 20a and 20b into voltage signals.

According to the differential amplifier 11 having such a configuration, each of the collector currents of the bipolar transistors 20a and 20b is modulated by the differential signals input from the nodes N1 and N5, whereby two output signals which are differential signals are generated at the output nodes N2 and N6 connected to the collectors of the bipolar transistors 21a and 21b.

The peak adjustment circuit 13 is a circuit that adjusts frequency characteristics of two output signals generated at the output nodes N2 and N6. The peak adjustment circuit 13 includes an output node (third node) N3, an output node (seventh node) N7, control nodes NCa and NCb, a series circuit (first series circuit) 60a including a capacitor (first capacitor) 80a and a variable resistance element (first variable resistance element) 32a, and a series circuit (second series circuit) 60b including a capacitor (second capacitor) 80b and a variable resistance element (second variable resistance element) 32b.

By the driver IC 5A, the positive-phase signal input to the node N1 and the negative-phase signal input to the node N5 are amplified by the differential amplifier 11 so as to have peaking characteristics, generated as the output signal in the output node N3 via the output node N2 and the series circuit 60a, and generated as the output signal in the output node N7 via the output node N6 and the series circuit 60b. Further, the output signal output to the output node N3 is output from the output node N4 via the source follower circuit 70a, and the output signal output from the output node N7 is output from the output node N8 via the source follower circuit 70b. In such a configuration, the variable resistance element 32a in the series circuit 60a is set to a variable first resistance value by the first setting signal, and the variable resistance element 32b in the series circuit 60b is set to a variable second resistance value by the second setting signal. Therefore, the peak frequency of the two output signals can be stabilized while the peak amounts of the two output signals are adjusted. As a result, the frequency characteristics of the output signals adjusted by the driver IC 5A of the present modification can be stabilized.

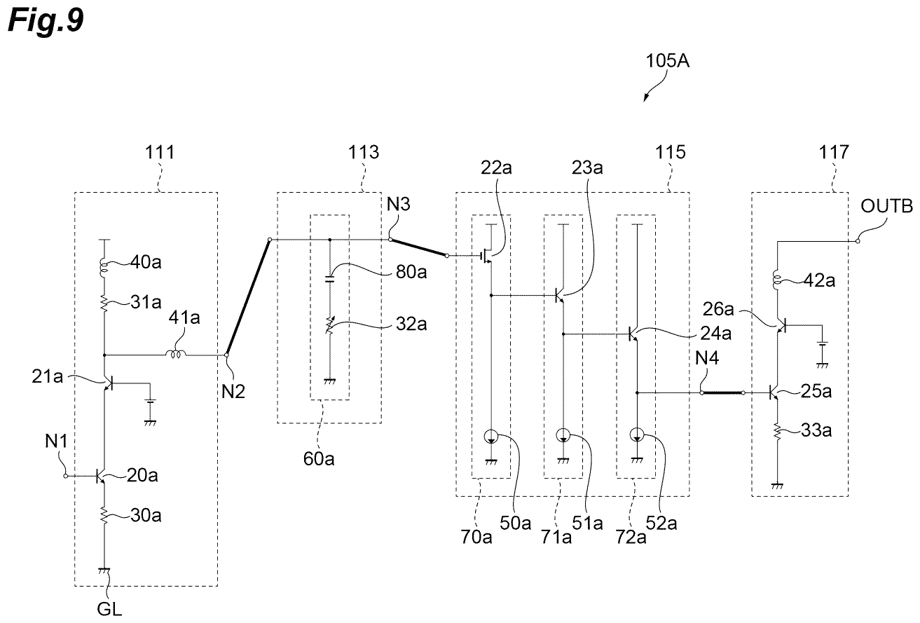

FIG. 9 is a circuit diagram illustrating a configuration of the driver IC 105A according to a modification of the present disclosure. The driver IC 105A is an embodiment in which the driver IC 105 is changed so that the amplifier 111 has a function of causing peaking characteristics.

That is, the driver IC 105A includes a node N1 and an amplifier 111 including bipolar transistors 20a and 21a, resistance elements 30a and 31a, an inductor 40a, an inductor 41A, and an output node N2. The amplifier 111 includes at least one of the inductor 40a and the inductor 41a, and the other may be omitted. The amplifier 111 generates a single-phase signal at the output node N2 having peaking characteristics according to the single-phase signals input.

In addition, the driver IC 105A includes, as the peak adjustment circuit 113, an output node N3, and a series circuit 60a configured by a capacitor 80a and a variable resistance element 32a.

According to such a modification, even in a configuration in which a circuit in the subsequent stage is driven by a single-phase signal, the frequency characteristics of the output signal adjusted by the driver IC 105A can be stabilized.

What is claimed is:

1. A peaking adjustment circuit comprising:
an amplifier circuit including a first node to which a first input signal is input and a second node as an output node;
an adjustment circuit including a third node as an output node, a first inductor connected between the second node and the third node, and a first series circuit connected between the third node and a ground wiring and having a first capacitor and a first variable resistance element connected in series with each other; and
a follower circuit including a fourth node as an output node, and a first source follower circuit connected between the third node and the fourth node,
wherein the first variable resistance element has a first resistance value that changes according to a first setting signal.

2. The peaking adjustment circuit according to claim 1, wherein
the first series circuit is a circuit in which the first capacitor and the first variable resistance element are connected in the order of the first capacitor, the first variable resistance element, between the third node and the ground wiring.

3. The peaking adjustment circuit according to claim 2, wherein
the first variable resistance element includes a field effect transistor having a drain connected to the first capacitor, a source connected to the ground wiring, and a gate to which the first setting signal is input.

4. The peaking adjustment circuit according to claim 1, wherein
the follower circuit further includes a first emitter follower circuit connected in cascade to the first source follower circuit between the first source follower circuit and the fourth node.

5. A peaking adjustment circuit comprising:
an amplifier circuit including a first node to which a first input signal is input, a fifth node to which a second input signal is input, and a second node and a sixth node as output nodes;
an adjustment circuit including a third node and a seventh node as output nodes, a first inductor connected between the second node and the third node, a first series circuit connected between the third node and a ground wiring and having a first capacitor and a first variable resistance element connected in series with each other, a second inductor connected between the sixth node and the seventh node, and a second series circuit connected between the seventh node and the ground wiring and having a second capacitor and a second variable resistance element connected in series with each other; and
a follower circuit including a fourth node and an eighth node as output nodes, a first source follower circuit connected between the third node and the fourth node, and a second source follower circuit connected between the seventh node and the eighth node, wherein
the first variable resistance element has a first resistance value that changes according to a first setting signal, and
the second variable resistance element has a second resistance value that changes according to a second setting signal.

6. The peaking adjustment circuit according to claim 5, wherein
the first series circuit is a circuit in which the first capacitor and the first variable resistance element are connected in the order of the first capacitor, the first variable resistance element, between the third node and the ground wiring, and
the second series circuit is a circuit in which the second capacitor and the second variable resistance element are connected in the order of the second capacitor, the second variable resistance element, between the seventh node and the ground wiring.

7. The peaking adjustment circuit according to claim 6, wherein
the first variable resistance element includes a field effect transistor having a drain connected to the first capacitor, a source connected to the ground wiring, and a gate to which the first setting signal is input, and
the second variable resistance element includes a field effect transistor having a drain connected to the second capacitor, a source connected to the ground wiring, and a gate to which the second setting signal is input.

8. The peaking adjustment circuit according to claim 5, wherein
the follower circuit
further includes:
a first emitter follower circuit connected in cascade to the first source follower circuit between the first source follower circuit and the fourth node; and
a second emitter follower circuit connected in cascade to the second source follower circuit between the second source follower circuit and the eighth node.

9. The peaking adjustment circuit according to claim 5, wherein
an inductance of the first inductor is equal to an inductance of the second inductor,
a capacitance value of the first capacitor is equal to a capacitance value of the second capacitor, and
a resistance value of the first variable resistance element and a resistance value of the second variable resistance element are set equal to each other.

10. A peaking adjustment circuit comprising: an amplifier circuit including a first node to which a first input signal is input and a second node as an output node, and generating an amplified signal having peaking characteristics according to the first input signal in the output node;
an adjustment circuit including a third node, and a first series circuit connected between the third node and a ground wiring and having a first capacitor and a first variable resistance element connected in series with each other; and
a follower circuit including a fourth node as an output node, and a first source follower circuit connected between the third node and the fourth node,
wherein the first variable resistance element has a first resistance value that changes according to a first setting signal.

11. A peaking adjustment circuit comprising:
an amplifier circuit including a first node to which a first input signal is input, a fifth node to which a second input signal is input, and a second node and a sixth node as output nodes, and generating an amplified signal having peaking characteristics according to the first input signal and the second input signal in the output node;
an adjustment circuit including a third node and a seventh node as output nodes, a first series circuit connected between the third node and a ground wiring and having a first capacitor and a first variable resistance element connected in series with each other, and a second series circuit connected between the seventh node and the ground wiring and having a second capacitor and a second variable resistance element connected in series with each other; and
a follower circuit including a fourth node and an eighth node as output nodes, a first source follower circuit connected between the third node and the fourth node, and a second source follower circuit connected between the seventh node and the eighth node, wherein
the first variable resistance element has a first resistance value that changes according to a first setting signal, and
the second variable resistance element has a second resistance value that changes according to a second setting signal.
